(19) United States
(12) Patent Application Publication
(10) Pub. No.: US 2025/0277811 A1
(43) Pub. Date: Sep. 4, 2025

(54) ELECTRICAL CONNECTION APPARATUS

(71) Applicant: Kabushiki Kaisha Nihon Micronics, Tokyo (JP)

(72) Inventors: Souichi KANOSUE, Oita (JP); Masataka KIMOTO, Oita (JP); Toshihisa KADOWAKI, Oita (JP); Shin SAKIYAMA, Oita (JP)

(21) Appl. No.: 19/059,123

(22) Filed: Feb. 20, 2025

(30) Foreign Application Priority Data
Mar. 1, 2024 (JP) 2024-031202

(51) Int. Cl. G01R 1/04; G01R 1/073

(52) U.S. Cl. CPC G01R 1/0416; G01R 1/07314

(57) ABSTRACT

An electrical connection apparatus includes: a probe head holding a probe; a wiring sheet including a first connection portion arranged on a first sheet surface facing the probe head and a second connection portion arranged on a second sheet surface; and a wiring board that is arranged facing the second sheet surface. A press-fit pin having an elastically deforming head is embedded in the wiring sheet, and the head is exposed from at least any of the first sheet surface and the second sheet surface. The head of the press-fit pin exposed from the first sheet surface is fitted into a recess formed in the probe head to fix the probe head to the wiring sheet. The head of the press-fit pin exposed from the second sheet surface is fitted into a recess formed in the wiring board to fix the wiring board to the wiring sheet.

### CROSS-REFERENCE TO RELATED APPLICATIONS

The present application is based on, and claims priority from Japanese Patent Application No. 2024-031202, filed on Mar. 1, 2024, the entire contents of which are incorporated herein by reference.

### TECHNICAL FIELD

The present disclosure relates to an electrical connection apparatus used for inspecting electrical characteristics of an object to be inspected.

### BACKGROUND ART

To measure electrical characteristics of an object to be inspected such as an integrated circuit, an electrical connection apparatus having a terminal for inspection in contact with the object to be inspected is used. In the measurement using the electrical connection apparatus, the object to be inspected is electrically connected to an inspection device such as a tester via the terminal for inspection. In order to measure characteristics of the object to be inspected, the electrical connection apparatus is configured by superimposing a plurality of circuit boards such as a printed board and a space transformer.

### CITATION LIST

### Patent Literature

[Patent Literature 1] JP 2019-178901 A

### SUMMARY

Conventionally, a plurality of circuit boards constituting an electrical connection apparatus are screwed and connected. When the circuit boards are connected by means of screwing, it takes time to replace the circuit boards. An object of the present disclosure is to provide an electrical connection apparatus having easily replaceable circuit boards.

An electrical connection apparatus according to one aspect of the present disclosure includes: a probe head holding a probe; a wiring sheet including a first connection portion arranged on a first sheet surface facing the probe head and a second connection portion arranged on a second sheet surface; and a wiring board that is arranged facing the second sheet surface. A press-fit pin having an elastically deforming head is embedded in the wiring sheet, and the head is exposed from at least any of the first sheet surface and the second sheet surface. The head of the press-fit pin exposed from the first sheet surface is fitted into a recess formed in the probe head to fix the probe head to the wiring sheet. The head of the press-fit pin exposed from the second sheet surface is fitted into a recess formed in the wiring board to fix the wiring board to the wiring sheet.

### BRIEF DESCRIPTION OF THE DRAWINGS

FIG. 1 is a schematic view showing a configuration of an electrical connection apparatus according to an embodiment.

FIG. 2 is a schematic plan view showing the configuration of the electrical connection apparatus according to the embodiment.

FIG. 3 is a schematic view showing a joined state using a press-fit pin of the electrical connection apparatus according to the embodiment.

FIG. 4 is a schematic view showing a joining method using a press-fit pin of the electrical connection apparatus according to the embodiment.

FIG. 5 is a schematic view showing another joined state using press-fit pins of the electrical connection apparatus according to the embodiment.

FIG. 6 is a schematic view showing another joining method using press-fit pins of the electrical connection apparatus according to the embodiment.

FIG. 7 is a schematic view showing an example of a head shape of a press-fit pin of the electrical connection apparatus according to the embodiment.

FIG. 8 is a schematic cross-sectional view showing a configuration example of a wiring sheet in the electrical connection apparatus according to the embodiment.

FIG. 9 is a schematic view showing an example of an internal circuit of the wiring sheet in the electrical connection apparatus according to the embodiment.

FIG. 10 is a schematic view showing another example of an internal circuit of the wiring sheet in the electrical connection apparatus according to the embodiment.

FIG. 11 is a schematic view showing another example of an internal circuit of the wiring sheet in the electrical connection apparatus according to the embodiment.

FIG. 12 is a schematic view showing an example of a loopback circuit using the wiring sheet shown in FIG. 11.

FIG. 13 is a schematic view showing another example of an internal circuit of the wiring sheet in the electrical connection apparatus according to the embodiment.

FIG. 14 is a schematic view showing another example of an internal circuit of the wiring sheet in the electrical connection apparatus according to the embodiment.

FIG. 15 is a schematic view showing an example of an arrangement of electronic circuits on the wiring sheet in the electrical connection apparatus according to the embodiment.

FIG. 16 is a schematic view showing another example of a wiring sheet and a circuit board in the electrical connection apparatus according to the embodiment.

### DETAILED DESCRIPTION

An embodiment will be described with reference to the drawings. In the description of the drawings below, the same or similar parts are denoted with the same or similar reference numerals. However, it should be noted that the drawings are schematically shown and the ratios of the thickness of each portion and the like are different from those in reality. Further, it is needless to say that the drawings include portions where the relationships and ratios of dimensions are different between drawings. The following embodiment exemplifies an apparatus and a method for embodying the technical concept of the present invention, and the embodiment does not specify the material, shape, structure, arrangement, and the like of components to the following.

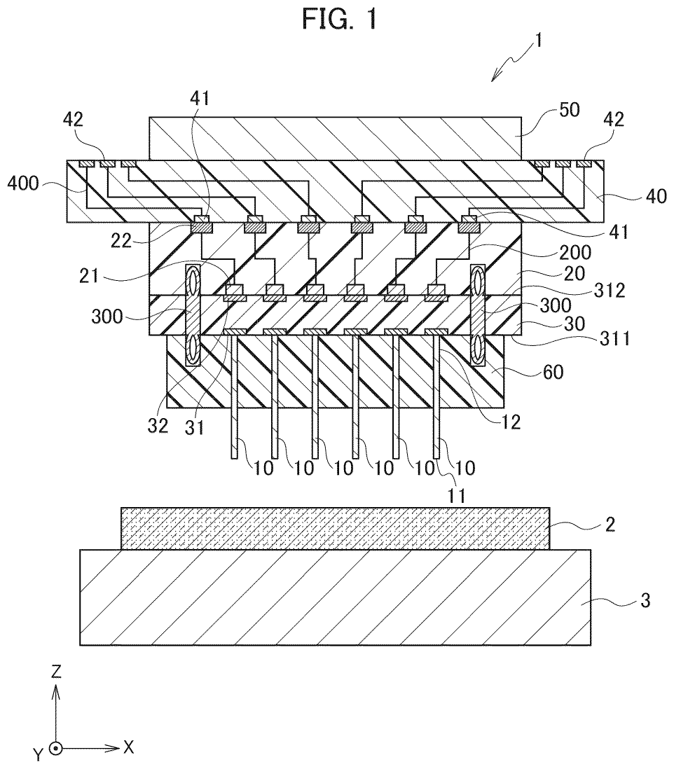

An electrical connection apparatus 1 according to an embodiment shown in FIG. 1 is used for inspecting an object 2 to be inspected. The electrical connection apparatus 1 includes probes 10, a probe head 60 holding the probes 10, a wiring sheet 30 laminated on the probe head 60, and a wiring board 20 laminated on the wiring sheet 30.

The electrical connection apparatus 1 further includes a printed board 40 laminated on the wiring board 20 and a stiffener 50 laminated on the printed board 40. In the following description, a direction in which the electrical connection apparatus 1 is located when viewed from the object 2 to be inspected is defined as an upward direction, and a direction in which the object 2 to be inspected is located when viewed from the electrical connection apparatus 1 is defined as a downward direction. As shown in FIG. 1, a direction from the downward direction to the upward direction is defined as a Z direction, and a plane perpendicular to the Z direction is defined as an XY plane. In FIG. 1, a left-right direction of the drawing is defined as an X direction, and a front-back direction is defined as a Y direction. Further, a surface facing the upward direction of each component of the electrical connection apparatus 1 will be referred to as an upper surface, and a surface facing the downward direction will be referred to as a lower surface.

The probes 10 function as terminals for inspection for electrically connecting the object 2 to be inspected and an inspection device. Each probe 10 has a tip 11 which is one end arranged so as to be in contact with the object 2 to be inspected and a proximal end 12 which is the other end connected to the tip 11. The probes 10 are held while passing through through-holes formed in the probe head 60, for example. Each tip 11 and each proximal end 12 are exposed from the probe head 60.

The wiring sheet 30 includes first connection portions 31 arranged on a first sheet surface 311 facing the probe head 60, and second connection portions 32 arranged on a second sheet surface 312 facing in an opposite direction of the first sheet surface 311. The first sheet surface 311 is a lower surface of the wiring sheet 30, and the second sheet surface 312 is an upper surface of the wiring sheet 30. In other words, the first sheet surface 311 and the second sheet surface 312 are main surfaces of the wiring sheet 30 facing in opposite directions. The wiring sheet 30 has an internal circuit (not shown in FIG. 1) electrically connected to at least any of the first connection portions 31 and the second connection portions 32. Each first connection portion 31 is connected to a proximal end 12 of each probe 10 which is exposed from the probe head 60. The wiring sheet 30 has flexibility and elastically deforms in a thickness direction. Details of the configuration of the wiring sheet 30 will be described later.

The wiring board 20 is arranged facing the probe head 60 with the wiring sheet 30 therebetween. First electrodes 21 electrically connected to the second connection portions 32 of the wiring sheet 30 are arranged on a lower surface of the wiring board 20 facing the second sheet surface 312 of the wiring sheet 30. Second electrodes 22 are arranged on an upper surface of the wiring board 20 facing the printed board 40. The first electrodes 21 and the second electrodes 22 are electrically connected via internal wiring 200. A multilayer wiring board such as a Multi-Layer Organic (MLO) board or a Multi-Layer Ceramic (MLC) board may be used for the wiring board 20, for example.

The printed board 40 is arranged facing the upper surface of the wiring board 20. The printed board 40 has first ends 41 arranged on a lower surface thereof facing the wiring board 20, second ends 42 arranged on an upper surface thereof, and wiring patterns 400 for electrically connecting the first ends 41 and the second ends 42. The second ends 42 are electrically connected to an inspection device (not shown), for example. As a result, an electrical signal propagates between the object 2 to be inspected and the inspection device via the electrical connection apparatus 1.

The object 2 to be inspected is mounted on a stage 3. The electrical connection apparatus 1 and the stage 3 are movable relative to one another in an up-down direction. When the object 2 to be inspected is inspected, a distance between the electrical connection apparatus 1 and the stage 3 is made small, and the tips 11 of the probes 10 contact signal terminals (not shown) of the object 2 to be inspected. FIG. 1 shows a state in which the probes 10 and the object 2 to be inspected are separated.

The wiring board 20 may be a space transformer that transforms a distance between the proximal ends 12 of the probes 10 to a distance between the first ends 41 of the printed board 40, when viewed from a direction normal to the upper surface of the wiring board 20, for example. Due to the wiring board 20 being the space transformer, it is possible to electrically connect the signal terminals arranged on the object 2 to be inspected to the second ends 42 of the printed board 40 which are arranged at a distance larger than a distance between the signal terminals. This facilitates the electrical connection between the wiring patterns 400 in the printed board 40 and the inspection device.

As shown in FIG. 1, the stiffener 50 may be laminated on the printed board 40. The stiffener 50 has higher stiffness than the printed board 40, and ensures the mechanical strength of the electrical connection apparatus 1 by preventing the printed board 40 from being bent. In addition, the stiffener 50 may be used as a support for fixing each component of the electrical connection apparatus 1.

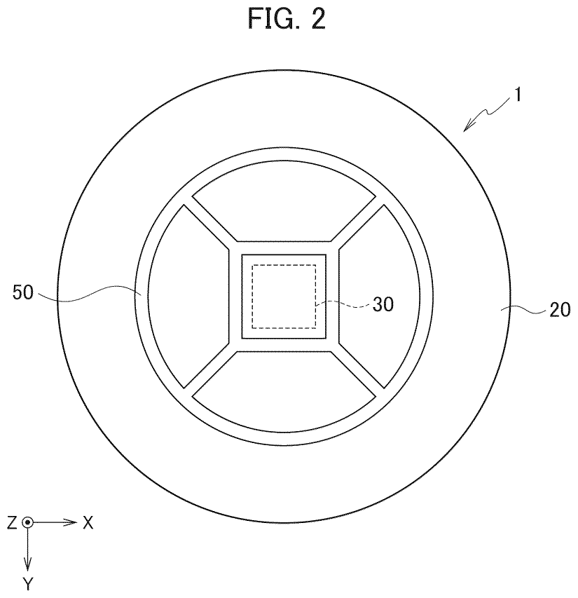

FIG. 2 is a plan view (hereinafter also referred to as “in plan view”) of a structure in which the wiring board 20, the wiring sheet 30, the printed board 40, and the stiffener 50 are laminated, as viewed from the Z direction. The stiffener 50 is arranged on an upper surface of the printed board 40 that is circular in plan view.

As shown in FIG. 2, the stiffener 50 has a shape in which an outer circular ring and an inner rectangular ring are connected using spokes, for example. The wiring board 20 and the wiring sheet 30 are arranged in the vicinity of the center of a lower surface of the printed board 40. The wiring board 20 and the printed board 40 are fixed with screws, and the printed board 40 and the stiffener 50 are fixed with screws, for example.

Meanwhile, as shown in FIG. 1, press-fit pins 300 are used for joining the probe head 60 and the wiring sheet 30, and for joining the wiring sheet 30 and the wiring board 20. Each press-fit pin 300 has heads which elastically deform in a direction perpendicular to an axial direction.

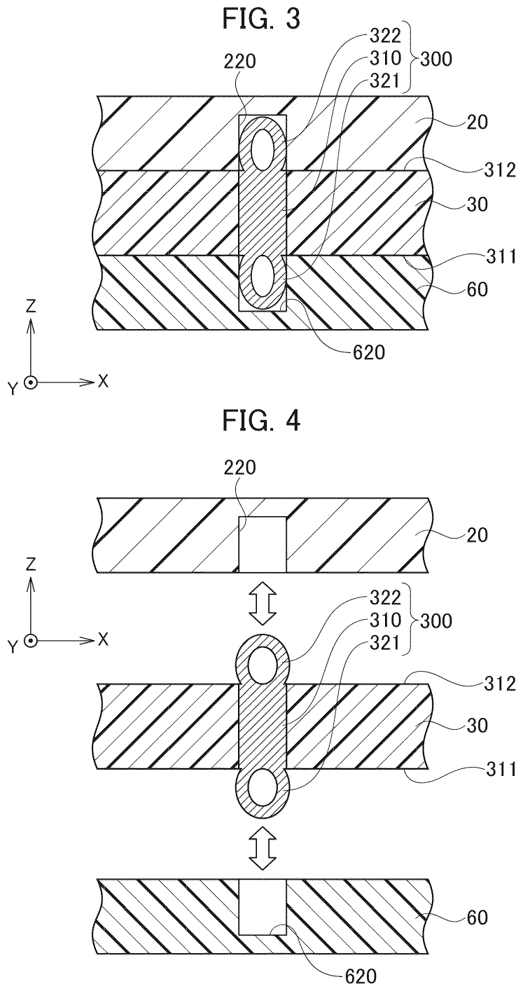

FIG. 3 shows an example of a joined state using a press-fit pin 300. The press-fit pin 300 shown in FIG. 3 has a main body 310 passing through the wiring sheet 30, from the first sheet surface 311 to the second sheet surface 312. A first head 321 connected to one end of the main body 310 is exposed from the first sheet surface 311. A second head 322 connected to the other end of the main body 310 is exposed from the second sheet surface 312. In the following, when each of the first head 321 and the second head 322 is not limited, the first head 321 and the second head 322 will be collectively referred to as a head 320. The head 320 may be ring-shaped, when viewed from a direction parallel to the XY plane, for example.

The first head 321 of the press-fit pin 300 exposed from the first sheet surface 311 is fitted into a recess formed in the probe head 60 (hereinafter referred to as “first recess 620”). This fixes the probe head 60 to the wiring sheet 30. The second head 322 of the press-fit pin 300 exposed from the second sheet surface 312 is fitted into a recess formed in the wiring board 20 (hereinafter referred to as “second recess 220”). This fixes the wiring board 20 to the wiring sheet 30.

FIG. 4 shows a state in which the probe head 60, the wiring sheet 30, and the wiring board 20 are separated. As shown in FIG. 4, the main body 310 of the press-fit pin 300 is fitted into a through-hole formed in the wiring sheet 30, for example. At this time, the first head 321 is exposed from the first sheet surface 311, and the second head 322 is exposed from the second sheet surface 312. Next, the first sheet surface 311 of the wiring sheet 30 is brought close to the probe head 60 to fit the first head 321 of the press-fit pin 300 into the first recess 620 formed in the probe head 60. Then, the second sheet surface 312 of the wiring sheet 30 is brought close to the wiring board 20 to fit the second head 322 of the press-fit pin 300 into the second recess 220 formed in the wiring board 20.

The order of joining the probe head 60, the wiring sheet 30, and the wiring board 20 is arbitrary. The wiring sheet 30 and the wiring board 20 may be joined after joining the probe head 60 and the wiring sheet 30, for example. Alternatively, the probe head 60 and the wiring sheet 30 may be joined after joining the wiring sheet 30 and the wiring board 20.

The first head 321 fitted into the first recess 620 formed in the probe head 60 is compressed and deformed. Due to an elastic force acting on the deformed first head 321 to return a shape thereof to an original shape, the probe head 60 and the wiring sheet 30 are joined. Similarly, the second head 322 fitted into the second recess 220 formed in the wiring board 20 is compressed and deformed. Due to an elastic force acting on the deformed second head 322 to return a shape thereof to an original shape, the wiring board 20 and the wiring sheet 30 are joined.

FIG. 4 shows a state of a press-fit pin 300 before the electrical connection apparatus 1 is assembled, for example. The press-fit pin 300 shown in FIG. 4 expands in the direction perpendicular to the axial direction, compared with the press-fit pin 300 shown in FIG. 3.

FIGS. 3 and 4 show examples of the press-fit pin 300 having the main body 310 embedded in the wiring sheet 30 and the heads 320 exposed from both the first sheet surface 311 and the second sheet surface 312. Alternatively, one head 320 connected to the main body 310 may be exposed only from either the first sheet surface 311 or the second sheet surface 312. In other words, the number of head 320 connected to the main body 310 may be one.

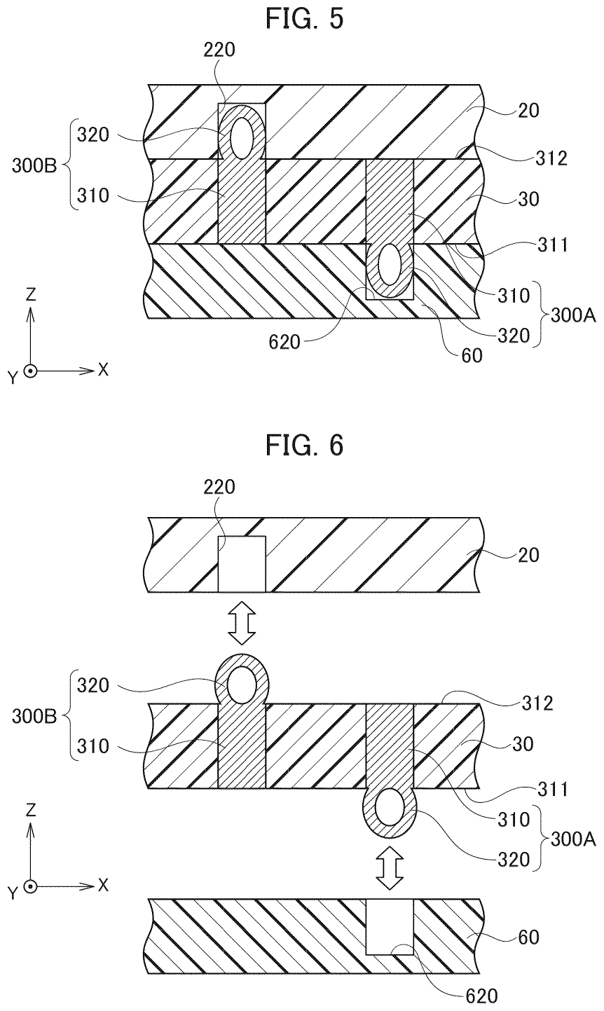

As shown in FIG. 5, the wiring sheet 30 and the probe head 60 are joined by means of a first press-fit pin 300A having one head 320 connected to a main body 310, for example. The head 320 of the first press-fit pin 300A is exposed from the first sheet surface 311. The wiring sheet 30 and the wiring board 20 may be joined by means of a second press-fit pin 300B having one head 320 connected to a main body 310. The head 320 of the second press-fit pin 300B is exposed from the second sheet surface 312.

As shown in FIG. 5, overlapping of positions of the first press-fit pin 300A and the second press-fit pin 300B is not necessary, in plan view viewed from a direction normal to a main surface of the wiring sheet 30. In other words, it is not necessary for a position of the press-fit pin 300 for joining the wiring sheet 30 and the probe head 60, to overlap a position of the press-fit pin 300 for joining the wiring sheet 30 and the wiring board 20 in plan view.

FIG. 6 shows a state in which the probe head 60, the wiring sheet 30, and the wiring board 20 shown in FIG. 5 are separated. As shown in FIG. 6, the main body 310 of the first press-fit pin 300A is fitted into a through-hole formed in the wiring sheet 30. At this time, the head 320 of the first press-fit pin 300A is exposed from the first sheet surface 311. Further, the main body 310 of the second press-fit pin 300B is fitted into a through-hole formed in the wiring sheet 30. At this time, the head 320 of the second press-fit pin 300B is exposed from the second sheet surface 312. Next, the first sheet surface 311 of the wiring sheet 30 is brought close to the probe head 60 to fit the head 320 of the first press-fit pin 300A into the first recess 620 formed in the probe head 60. Then, the second sheet surface 312 of the wiring sheet 30 is brought close to the wiring board 20 to fit the head 320 of the second press-fit pin 300B into the second recess 220 formed in the wiring board 20. As a result, the probe head 60 and the wiring sheet 30 are fixed, and the wiring board 20 and the wiring sheet 30 are fixed by an elastic force of the head 320.

When the press-fit pin 300 has two heads 320, one of the heads 320 is fitted into one of the first recess 620 and the second recess 220, and then the other of the heads 320 is fitted into the other of the recesses. Therefore, there is a possibility that the other head 320 which is fitted into the other recess later than the one head may become slightly thin before being fitted. If the thinned head 320 is fitted into the recess, a joining force deteriorates. Due to the press-fit pin 300 having one head 320, the widely expanded head 320 can be fitted into the second recess 220 and the first recess 620.

Further, by using the press-fit pin 300 having one head 320, the degrees of freedom of an arrangement position of the first recess 620 formed in the probe head 60 and an arrangement position of the second recess 220 formed in the wiring board 20 increase. The second recess 220 can be formed by avoiding positions where the first electrodes 21 and the second electrodes 22 of the wiring board 20 are arranged and positions where the pieces of internal wiring 200 are arranged, for example.

An arrangement position of the press-fit pin 300 can be arbitrarily set to the extent of not affecting functions of the electrical connection apparatus 1. Press-fit pins 300 may be arranged at four corners of a rectangular wiring sheet 30 in plan view, for example. Further, press-fit pins 300 may be arranged at any position in addition to the four corners of the wiring sheet 30.

Any material may be used for the press-fit pin 300, but a metal material may be used for the press-fit pin 300, for example. By using the press-fit pin 300 made of a metal material, the wiring sheet 30 can be joined to the probe head 60 and the wiring board 20 with a strong holding force. However, an insulating material may be used for the press-fit pin 300. When it is desired to ensure electrical insulation between the wiring sheet 30 and the probe head 60, or electrical insulation between the wiring sheet 30 and the wiring board 20, an insulating material may be used for the press-fit pin 300, for example.

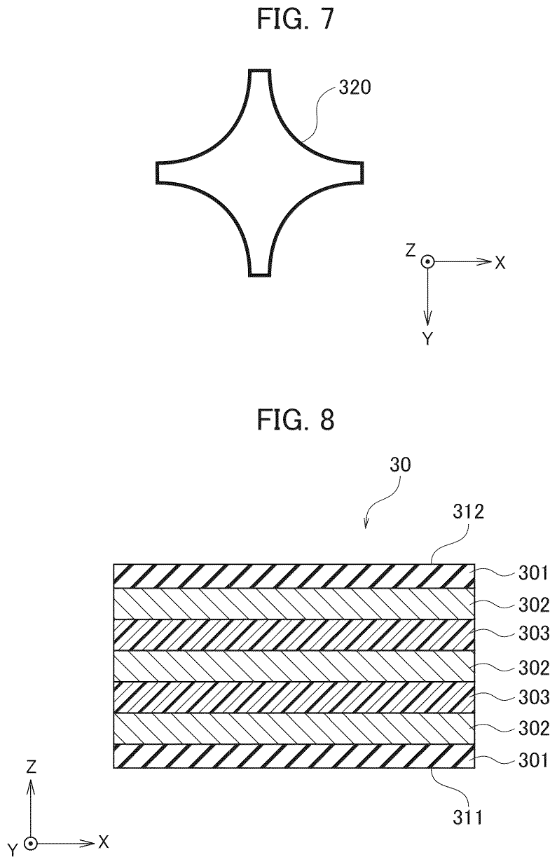

The head 320 of the press-fit pin may have any shape in plan view. When viewed from an axial direction of the press-fit pin 300, the head 320 thereof may be circular or star-shaped as shown in FIG. 7, for example.

When a plurality of press-fit pins 300 are arranged in the wiring sheet 30, the maximum value of a diameter perpendicular to an axial direction of each of heads 320 (hereinafter also referred to as “maximum diameter”) may be the same for all heads 320. Maximum diameters of all heads 320 exposed from the first sheet surface 311 may be the same, for example. Further, maximum diameters of all heads 320 exposed from the second sheet surface 312 may be the same. Heads 320 exposed from the first sheet surface 311 of the wiring sheet 30 and heads 320 exposed from the second sheet surface 312 may have the same maximum diameter.

Meanwhile, a head 320 exposed from the first sheet surface 311 and a head 320 exposed from the second sheet surface 312 may have different maximum diameters. A maximum diameter of the head 320 exposed from the first sheet surface 311 may be made larger than a maximum diameter of the head 320 exposed from the second sheet surface 312, for example. Therefore, when inner diameters of the first recess 620 and the second recess 220 are the same, a joining force generated between the first recess 620 and the head 320 becomes larger than a joining force generated between the second recess 220 and the head 320. As a result, when the wiring board 20 is removed from the wiring sheet 30, heads 320 of all press-fit pins 300 can be fitted into the probe head 60. In other words, this eliminates a press-fit pin 300 having a head 320 fitted into the wiring board 20.

Alternatively, a maximum diameter of the head 320 exposed from the second sheet surface 312 may be made larger than a maximum diameter of the head 320 exposed from the first sheet surface 311. Therefore, when inner diameters of the first recess 620 and the second recess 220 are the same, a joining force generated between the second recess 220 and the head 320 becomes larger than a joining force generated between the first recess 620 and the head 320. As a result, when the probe head 60 is removed from the wiring sheet 30, heads 320 of all press-fit pins 300 can be fitted into the wiring board 20. In other words, this eliminates a press-fit pin 300 having a head 320 fitted into the probe head 60.

As described above, due to the head 320 exposed from the first sheet surface 311 and the head 320 exposed from the second sheet surface 312 having different maximum diameters, heads 320 of press-fit pins 300 can be fitted into either the probe head 60 or the wiring board 20. This can suppress the wiring sheet 30 from being pulled in two directions by a press-fit pin 300 having a head 320 fitted into the probe head 60 and a press-fit pin 300 having a head 320 fitted into the wiring board 20, and also can suppress films formed on surfaces of the wiring sheet 30 from being peeled off.

Further, when the head 320 exposed from the first sheet surface 311 and the head 320 exposed from the second sheet surface 312 have the same maximum diameter, an inner diameter of the first recess 620 formed in the probe head 60 and an inner diameter of the second recess 220 formed in the wiring board 20 may be different. The inner diameter of the first recess 620 may be made smaller than the inner diameter of the second recess 220, for example. Therefore, a joining force generated between the first recess 620 and the head 320 becomes larger than a joining force generated between the second recess 220 and the head 320. As a result, when the wiring board 20 is removed from the wiring sheet 30, heads 320 of all press-fit pins 300 can be fitted into the probe head 60.

Alternatively, an inner diameter of the second recess 220 may be made smaller than an inner diameter of the first recess 620. Therefore, a joining force generated between the second recess 220 and the head 320 becomes larger than a joining force generated between the first recess 620 and the head 320. As a result, when the probe head 60 is removed from the wiring sheet 30, heads 320 of all press-fit pins 300 can be fitted into the wiring board 20.

As described above, due to the first recess 620 and the second recess 220 having different inner diameters, heads 320 of press-fit pins 300 can be fitted into either the probe head 60 or the wiring board 20. This can suppress the wiring sheet 30 from being pulled in two directions by a press-fit pin 300 having a head 320 fitted into the probe head 60 and a press-fit pin 300 having a head 320 fitted into the wiring board 20, and also can suppress films formed on surfaces of the wiring sheet 30 from being peeled off.

The wiring sheet 30 may have a structure in which a conductive film and an insulating film are laminated. An internal circuit may be constituted from a conductive pattern formed on a conductive film, for example. FIG. 8 shows an example of a configuration of the wiring sheet 30. The wiring sheet 30 shown in FIG. 8 has a structure in which a laminated body constituted by conductive films 302 and insulating films 303 is interposed between a pair of cover films 301 of insulating materials. The number of laminated bodies constituted by the conductive films 302 and the insulating films 303 can be set to any number. The conductive films 302 may be metal materials such as copper foils, for example. The insulating films 303 may be insulating materials such as polyimide sheets, for example. The cover films 301 may be insulating materials such as solder resists, for example. An adhesive may be used for joining the conductive films 302, the insulating films 303, and the cover films 301 each other, for example. The wiring sheet 30 may have a structure in which a film (also referred to as a “base film”) of an insulating material is further interposed between laminated bodies including the conductive films 302 and the insulating films 303.

The wiring sheet 30 may be selected from among a plurality of wiring sheet candidates. Each of the wiring sheet candidates has a first connection portion 31 arranged on the first sheet surface 311, a second connection portion 32 arranged on the second sheet surface 312, and an internal circuit. Each of the wiring sheet candidates may include an internal circuit having a configuration different from that of another wiring sheet candidate. One wiring sheet 30 selected from among the plurality of wiring sheet candidates may be configured in an attachable/detachable manner between the probe head 60 and the wiring board 20.

An example of the configuration of wiring sheet candidates included in a wiring sheet group will be described below. In the following, when each of the wiring sheet candidates is not limited, the wiring sheet candidates will be collectively referred to as a wiring sheet 30.

An internal circuit of a wiring sheet 30 as any one of the group of wiring sheets may include a circuit for electrically connecting the first connection portions 31 and the second connection portions 32 (hereinafter also referred to as an “interposer circuit”). When the interposer circuit is formed on the wiring sheet 30 having the structure shown in FIG. 8, wiring is formed, which passes through the cover films 301, the conductive films 302, and the insulating films 303, from the first sheet surface 311 to the second sheet surface 312 of the wiring sheet 30, for example.

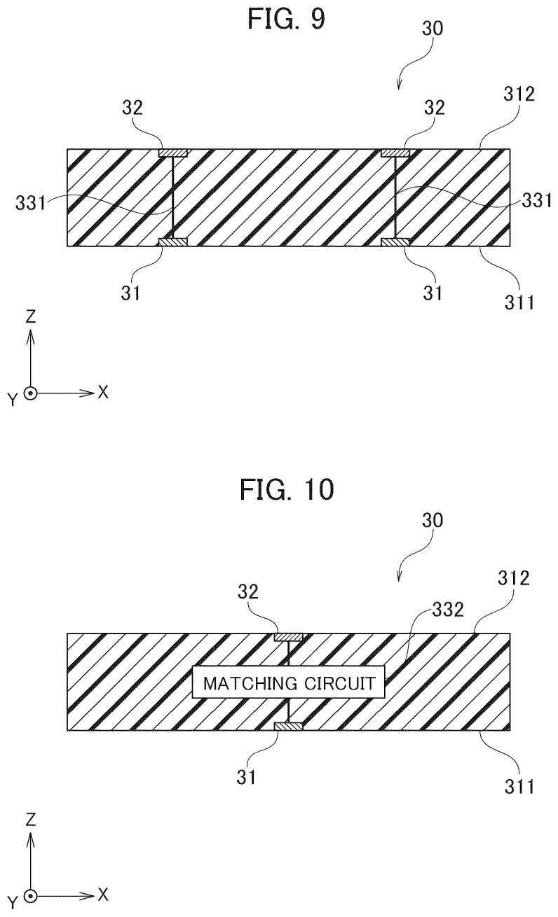

If the internal circuit of the wiring sheet 30 includes the interposer circuit, the internal circuit of the wiring sheet 30 shown in FIG. 9 may include a circuit for short-circuiting the first connection portions 31 and the second connection portions 32. In the internal circuit of the wiring sheet 30 shown in FIG. 9, the first connection portions 31 and the second connection portions 32 are electrically short-circuited by short-circuit wiring 331.

By attaching the wiring sheet 30 shown in FIG. 9 to the electrical connection apparatus 1, the probes 10 and the wiring patterns 400 in the printed board 40 are short-circuited via the internal circuit of the wiring sheet 30. This electrically connects the object 2 to be inspected and the inspection device. As a result, an electrical signal propagates between an inspection device such as an IC tester and the object 2 to be inspected and characteristics of the object 2 to be inspected are measured. One first connection portion 31 and one second connection portion 32 are connected in a one-to-one relationship by means of the internal circuit of the wiring sheet 30, for example. Alternatively, one first connection portion 31 may be connected to a plurality of second connection portions 32, or a plurality of first connection portions 31 may be connected to one second connection portion 32 by means of the internal circuit.

When the internal circuit of the wiring sheet 30 includes the interposer circuit, the internal circuit may include a matching circuit 332 having a first terminal connected to a first connection portion 31 and a second terminal connected to a second connection portion 32 as shown in FIG. 10. The matching circuit 332 may perform impedance matching between the first connection portion 31 and the second connection portion 32. The matching circuit 332 may include a x-type filter, for example.

The internal circuit of the wiring sheet 30 may include a circuit for electrically connecting any one of the first connection portions 31 and another one of the first connection portions 31. In other words, the internal circuit of the wiring sheet 30 may include a circuit for electrically connecting an output terminal and an input terminal of the object 2 to be inspected (hereinafter also referred to as a “loopback circuit”). Two signal terminals of the object 2 to be inspected are electrically connected by the loopback circuit.

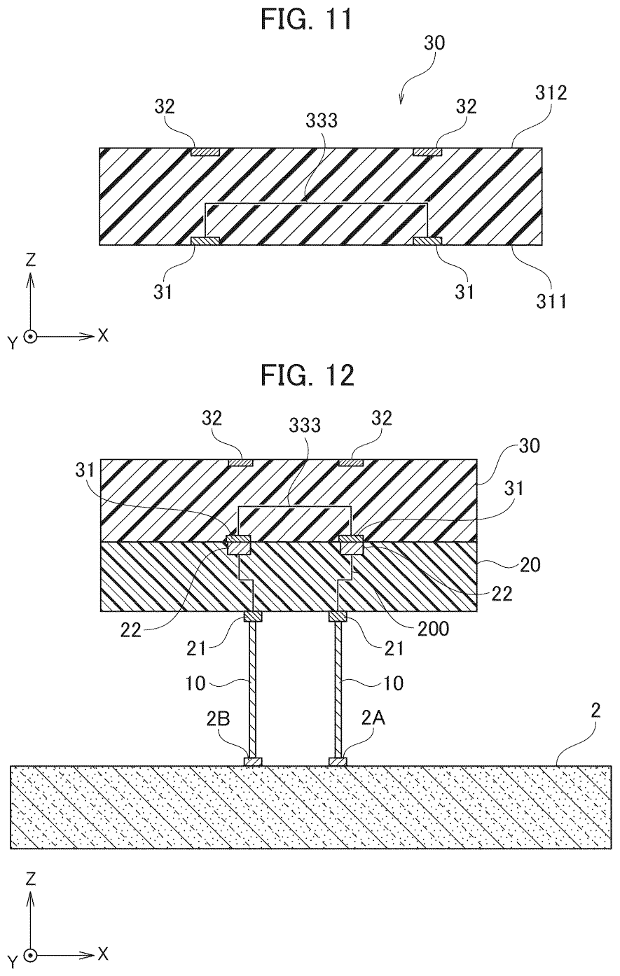

The internal circuit of the wiring sheet 30 may include a circuit for short-circuiting any one of the first connection portions 31 and another one of the first connection portions 31 as shown in FIG. 11, for example. In the internal circuit of the wiring sheet 30 shown in FIG. 11, the one first connection portion 31 and the other first connection portion 31 are electrically short-circuited by loopback wiring 333. By attaching the wiring sheet 30 shown in FIG. 11 to the electrical connection apparatus 1, one of the probes 10 and another one of the probes 10 are short-circuited via the internal circuit of the wiring sheet 30. This electrically connects one signal terminal and the other signal terminal of the object 2 to be inspected.

FIG. 12 shows a configuration in which a first signal terminal 2A of the object 2 to be inspected in contact with one of the probes 10, and a second signal terminal 2B of the object 2 to be inspected in contact with another one of the probes 10 are electrically connected via the loopback wiring 333 of the wiring sheet 30. Suppose that the object 2 to be inspected is a receiving circuit, the first signal terminal 2A is an output terminal of the object 2 to be inspected, and the second signal terminal 2B is an input terminal of the object 2 to be inspected, for example. In the above case, a transmission test can be performed by returning an output from the object 2 to be inspected to an input. In other words, it is possible to test whether an output portion and an input portion of the object 2 to be inspected are functioning normally, even if there is no destination equipment for transmission. As an inspection in accordance with a jitter tolerance test performed for the receiving circuit, an output signal output from the first signal terminal 2A (output terminal) may be input to the second signal terminal 2B (input terminal) as an input signal to inspect whether a specified error rate is ensured, for example.

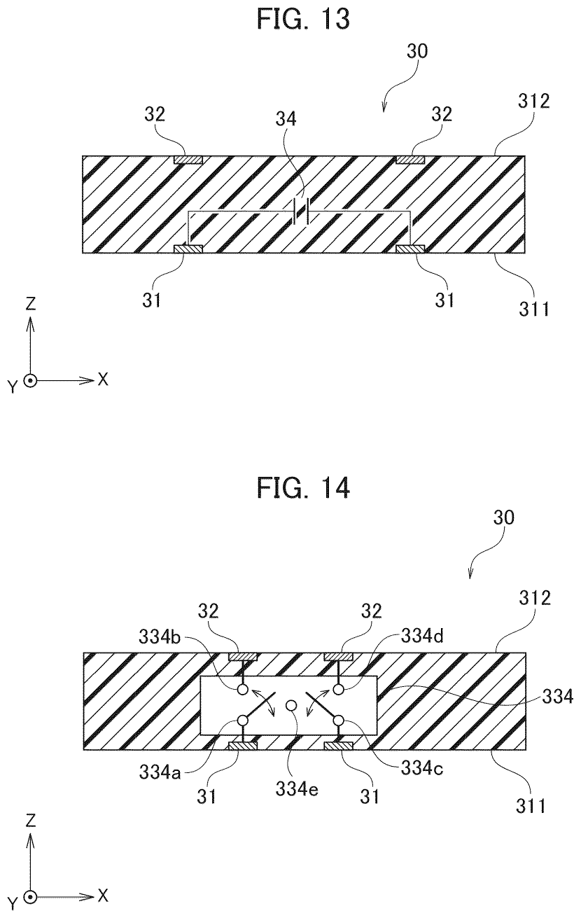

When the internal circuit of the wiring sheet 30 includes the loopback circuit, the internal circuit may include a circuit having a capacitor 34 connected in series between any one of the first connection portions 31 and another one of the first connection portions 31 as shown in FIG. 13. One terminal of the capacitor 34 is connected to the one first connection portion 31, and the other terminal of the capacitor 34 is connected to the other first connection portion 31. The capacitor 34 may be a capacitor formed using a semiconductor manufacturing process (hereinafter also referred to as a “process capacitor”).

Further, the internal circuit of the wiring sheet 30 may include a relay circuit that switches to electrically connect one of the first connection portions 31 to either one of the second connection portions 32 or another one of the first connection portions 31. The internal circuit shown in FIG. 14 includes a relay circuit 334 that constitutes either the interposer circuit for connecting a first connection portion 31 and a second connection portion 32 or the loopback circuit for connecting first connection portions 31 each other, for example.

When the relay circuit 334 shown in FIG. 14 constitutes the interposer circuit, a first contact terminal 334a and a second contact terminal 334b are connected, and a third contact terminal 334c and a fourth contact terminal 334d are connected. This electrically connects a first connection portion 31 and a second connection portion 32. When the relay circuit 334 constitutes the loopback circuit, the first contact terminal 334a and a common contact terminal 334e of the relay circuit 334 are connected, and the third contact terminal 334c and the common contact terminal 334e are connected. This electrically connects one of the first connection portions 31 and another one of the first connection portions 31.

Although examples of the internal circuit of the wiring sheet 30 have been described with reference to FIGS. 9 to 14, it is needless to say that the configuration of the internal circuit is not limited to the above. The internal circuit may include an inductor instead of the capacitor 34 shown in FIG. 13, or the internal circuit may include both a capacitor and an inductor, for example. In other words, the internal circuit of the wiring sheet 30 may include a passive circuit including any element. Further, the internal circuit may include a switching circuit using a diode or the like instead of the relay circuit 334 shown in FIG. 14.

An element included in the internal circuit of the wiring sheet 30 may be formed using a Micro Electro Mechanical Systems (MEMS) process, for example. By using the MEMS process, an element which is reduced in size can be formed integrally with the wiring sheet 30.

As described above, various circuit configurations as shown in FIGS. 9 to 14 can be implemented in the electrical connection apparatus 1 by merely replacing the wiring sheet 30 in the electrical connection apparatus 1, for example. Therefore, a plurality of types of measurements can be performed on the object 2 to be inspected using the electrical connection apparatus 1. A DC test may be performed on the object 2 to be inspected by mounting, in the electrical connection apparatus 1, the wiring sheet 30 including the internal circuit for short-circuiting the first connection portion 31 and the second connection portion 32, for example. Further, a high-frequency test may be performed on the object 2 to be inspected by mounting, in the electrical connection apparatus 1, the wiring sheet 30 including the internal circuit having the matching circuit or the loopback circuit.

Further, by arranging the relay circuit 334 in the wiring sheet 30 shown in FIG. 14 of the electrical connection apparatus 1, the wiring length of the interposer circuit and the loopback circuit can be reduced, compared to that when a relay element is arranged on the printed board 40. As a result, according to the electrical connection apparatus 1, it is possible to shorten a propagation path of an electrical signal and suppress the loss of an electrical signal and noise.

Further, by arranging the matching circuit 332 in the wiring sheet 30 shown in FIG. 10 of the electrical connection apparatus 1, wiring connected to the matching circuit 332 can be shortened. The matching circuit 332 can be arranged in the immediate vicinity of wiring for which impedance matching is to be performed, and therefore impedance matching can be performed effectively, for example.

As described above, the electrical connection apparatus 1 has the wiring sheet 30 including the internal circuit capable of constituting any circuit, which is interposed between the wiring board 20 and the printed board 40 in an attachable/detachable manner, and therefore it is possible to configure an arbitrary measurement system. As a result, characteristics of the object 2 to be inspected can be measured with high accuracy with the electrical connection apparatus 1.

Further, the wiring sheet 30 with flexibility in the thickness direction, which is interposed between the probe head 60 and the wiring board 20 in the electrical connection apparatus 1, can mitigate warpages and irregularities of surfaces of the probe head 60 and the wiring board 20. This can suppress the rattling and contact failure of the electrical connection apparatus caused by a gap between the probe head 60 and the wiring board 20.

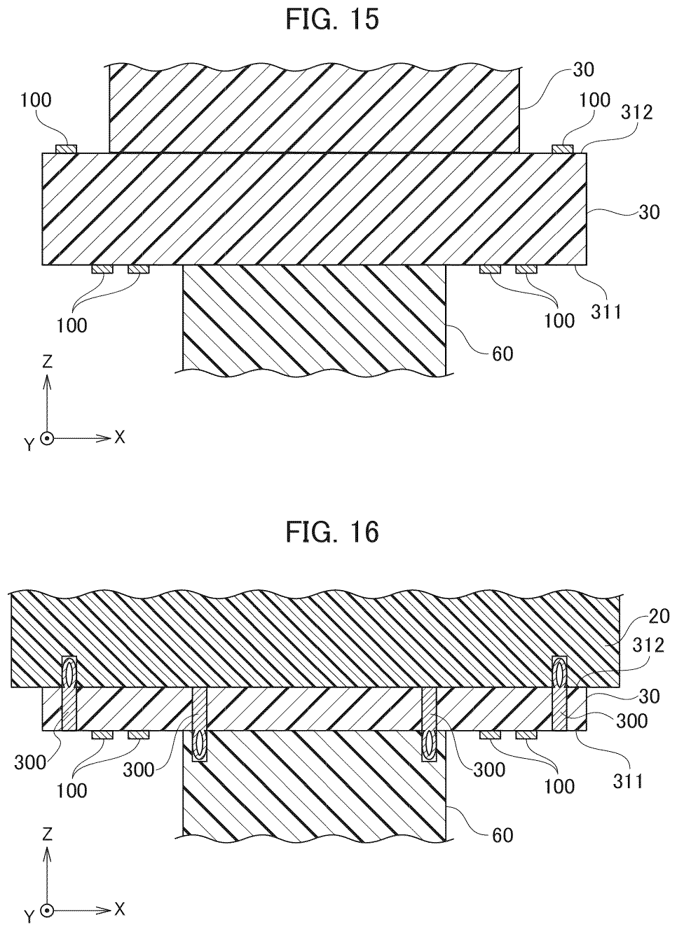

Further, electronic components electrically connected to the internal circuit can be arranged on a surface of the wiring sheet 30 in the electrical connection apparatus 1. As shown in FIG. 15, electronic components 100 connected to the internal circuit of the wiring sheet 30 may be arranged on both of the first sheet surface 311 and the second sheet surface 312, for example. Each electronic component 100 may be a capacitor, an inductor, or a resistance element, for example. FIG. 15 shows an example of arranging the electronic components 100 on both of the first sheet surface 311 and the second sheet surface 312, but the electronic components 100 may be arranged on either the first sheet surface 311 or the second sheet surface 312. By arranging the electronic components 100 on a surface of the wiring sheet 30, it is possible to reduce or divide the number of electronic components arranged on the wiring board 20 or the printed board 40, for example. Further, by arranging electronic components on the surface of the wiring sheet 30, it is possible to reduce the wiring length between the object 2 to be inspected and each electronic component. Therefore, by arranging electronic components such as capacitors for reducing power source noise on the wiring sheet 30, it is possible to stably perform measurements on the object 2 to be inspected, for example.

When the electronic components 100 are arranged on the surface of the wiring sheet 30, ends of the wiring sheet 30 that extend outward from the probe head 60 in plan view may hang downward. Therefore, as shown in FIG. 16, outer edges of the wiring board 20 may be positioned outward from outer edges of the wiring sheet 30 in plan view. By arranging press-fit pins 300 for joining the wiring sheet 30 and the wiring board 20 outside the electronic components 100 arranged on the wiring sheet 30, it is possible to prevent the ends of the wiring sheet 30 from hanging down. FIG. 16 shows an example of using each press-fit pin 300 having one head 320 for joining the probe head 60 and the wiring sheet 30, but each press-fit pin 300 having two heads 320 may be used to join the probe head 60 and the wiring sheet 30.

As described above, in the electrical connection apparatus 1, press-fit pins 300 are used for joining the probe head 60 and the wiring sheet 30, and for joining the wiring board 20 and the wiring sheet 30. This facilitates attachment and detachment of the probe head 60 to and from the wiring sheet 30 in the electrical connection apparatus 1, compared to when the probe head 60, the wiring sheet 30, and the wiring board 20 are screwed and joined. Therefore, the wiring sheet 30 can be easily replaced.

In addition, by using a press-fit pin 300 instead of a screw, it is not necessary to perform processing to form a screw hole, and the production of the electrical connection apparatus becomes easy. An inner diameter of each of the first recess 620 and the second recess 220 is formed smaller than an inner diameter of a screw hole. This can reduce the damage caused when the probe head 60 and the wiring board 20 are processed.

Further, by using the press-fit pin 300, it is possible to use the second recess 220 having a smaller inner diameter than the screw hole. This enhances the degree of freedom of the arrangement of the electrodes and wiring of the wiring board 20. The wiring board 20 is likely to trap heat inside by the difference between the inner diameter of the screw hole and the inner diameter of the recess. This can increase the heat capacity.

### Other Embodiments

Although an embodiment of the present invention has been described above, the discussion and drawings forming part of this disclosure should not be construed as limiting the invention. Various alternative embodiments, examples, and operational techniques will be apparent to those skilled in the art from this disclosure.

The wiring sheet 30 may include an internal circuit in which a plurality of types of circuit configurations are mixed, for example. The wiring sheet 30 may include an internal circuit in which the short-circuit wiring 331 and the matching circuit 332 are mixed, for example. Alternatively, the wiring sheet 30 may include an internal circuit in which an interposer circuit and a loopback circuit are mixed. The internal circuit may include the short-circuit wiring 331, the matching circuit 332, and the loopback wiring 333, or may further include the relay circuit 334, for example. Further, the loopback circuit may include the matching circuit 332. In this way, any circuit can be configured in the internal circuit of the wiring sheet 30.

As described above, by mounting, in the electrical connection apparatus 1, the wiring sheet 30 including the internal circuit in which any circuit configurations are mixed, a plurality of types of measurements can be performed on the object 2 to be inspected with one wiring sheet 30.

In the case described above, terminals for inspection that contact signal terminals of the object 2 to be inspected are the probes 10. When the terminals for inspection are the probes 10, it is possible to measure electrical characteristics of an object 2 to be inspected not separated from a wafer or an object 2 to be inspected which is converted into a chip, for example. Meanwhile, the wiring sheet 30 may be mounted in an electrical connection apparatus including a test socket, to support the measurement of electrical characteristics of the object 2 to be inspected performed in a state where the object 2 to be inspected is mounted in a package or the like. The test socket may be arranged on the wiring sheet 30, the test socket having a terminal for inspection connected to an external terminal of the package in which the object 2 to be inspected is mounted, instead of the probes 10 in the electrical connection apparatus 1 shown in FIG. 1, for example.

In this way, it is needless to say that the present invention includes various embodiments not described above. Therefore, the technical scope of the present invention is defined only by matters specified in the invention that are within the scope of claims appropriate from the above description.

### REFERENCE SIGNS LIST

1 Electrical connection apparatus
2 Object to be inspected
10 Probe
11 Tip
12 Proximal end
20 Wiring board
21 First electrode
22 Second electrode
30 Wiring sheet
31 First connection portion
32 Second connection portion
40 Printed board
41 First end
42 Second end
50 Stiffener
60 Probe head
100 Electronic component
200 Internal wiring
220 Second recess
300 Press-fit pin
310 Main body
311 First sheet surface
312 Second sheet surface
320 Head
321 First head
322 Second head
400 Wiring pattern
620 First recess

What is claimed is:

1. An electrical connection apparatus used for inspecting an object to be inspected, the electrical connection apparatus comprising:
a terminal for inspection having a tip arranged so as to be in contact with the object to be inspected and a proximal end connected to the tip;
a probe head holding the terminal for inspection;
a wiring sheet with flexibility including a first connection portion arranged on a first sheet surface facing the probe head and a second connection portion arranged on a second sheet surface facing in an opposite direction of the first sheet surface; and
a wiring board that is arranged facing the second sheet surface and includes a first electrode which is electrically connected to the second connection portion, wherein
a press-fit pin has a head that elastically deforms in a direction perpendicular to an axial direction and a main body that is embedded in the wiring sheet, the head being exposed from at least any of the first sheet surface and the second sheet surface,
the head of the press-fit pin exposed from the first sheet surface is fitted into a recess formed in the probe head to fix the probe head to the wiring sheet, and
the head of the press-fit pin exposed from the second sheet surface is fitted into a recess formed in the wiring board to fix the wiring board to the wiring sheet.

2. The electrical connection apparatus according to claim 1, wherein
the head is provided in plurality, and the press-fit pin has the main body passing through the wiring sheet, from the first sheet surface to the second sheet surface,
a first head of the heads connected to one end of the main body is exposed from the first sheet surface, and
a second head of the heads connected to the other end of the main body is exposed from the second sheet surface.

3. The electrical connection apparatus according to claim 1, wherein
the head connected to the main body of the press-fit pin is exposed only from either the first sheet surface or the second sheet surface.

4. The electrical connection apparatus according to claim 1, wherein
the press-fit pin is a metal material.

5. The electrical connection apparatus according to claim 1, wherein
the head is star-shaped when viewed from the axial direction of the press-fit pin.

6. The electrical connection apparatus according to claim 1, wherein
an outer edge of the wiring board is positioned outward from an outer edge of the wiring sheet in plan view.

7. The electrical connection apparatus according to claim 1, wherein
a maximum diameter of the head exposed from the first sheet surface is different from a maximum diameter of the head exposed from the second sheet surface.

8. The electrical connection apparatus according to claim 1, wherein
an inner diameter of the recess formed in the probe head is different from an inner diameter of the recess formed in the wiring board.

9. The electrical connection apparatus according to claim 1, wherein
the wiring sheet has a structure in which a laminated body constituted by a conductive film and an insulating film is interposed between cover films of an insulating material.

10. The electrical connection apparatus according to claim 1, wherein
the wiring board includes a second electrode electrically connected to the first electrode via internal wiring,
the electrical connection apparatus further comprising:
a printed board that is arranged facing the wiring board and has a wiring pattern connected to the second electrode.

11. The electrical connection apparatus according to claim 10, wherein
the terminal for inspection is provided in plurality, the wiring pattern is provided in plurality, and the wiring board is a space transformer that transforms a distance between the terminals for inspection into a distance between the wiring patterns of the printed board, when viewed from a direction normal to a main surface of the wiring board.

12. The electrical connection apparatus according to claim 1, wherein
the terminal for inspection is a probe having a tip that is arranged so as to be in contact with a signal terminal of the object to be inspected and a proximal end connected to the first connection portion of the wiring sheet.

13. The electrical connection apparatus according to claim 1, wherein
the terminal for inspection is arranged in a test socket connected to an external terminal of a package in which the object to be inspected is mounted.
